(19) United States
(12) Patent Application Publication
(10) Pub. No.: US 2026/0369310 A1
(43) Pub. Date: Nov. 19, 2026

(54) INTERNAL VOLTAGE GENERATING CIRCUITS AND METHODS OF GENERATING INTERNAL VOLTAGE

(71) Applicant: SK hynix Inc., Icheon-si Gyeonggi-do (KR)

(72) Inventor: Hyun Mo SUNG, Icheon-si Gyeonggi-do (KR)

(73) Assignee: SK hynix Inc., Icheon-si Gyeonggi-do (KR)

(21) Appl. No.: 19/317,493

(22) Filed: Sep. 3, 2025

(30) Foreign Application Priority Data
May 15, 2025 (KR) 10-2025-0063533

(51) Int. Cl. G11C 5/14

(52) U.S. Cl. CPC G11C 5/147

(57) ABSTRACT

An internal voltage generating circuit includes a calibration voltage generating circuit configured to generate a calibration voltage, a voltage level of the calibration voltage being changed based on changes of ambient temperature, reference voltage variation, and process changes, a drive control signal generating circuit configured to drive a drive control signal based on a sense amplifier activation signal used to activate a bit line sense amplifier that senses and amplifies a bit line based on the calibration voltage, and a pull-up signal generating circuit configured to generate a plurality of pull-up signals used to drive an internal voltage based on a feedback voltage generated by voltage-dividing the internal voltage and the drive control signal.

### CROSS-REFERENCE TO RELATED APPLICATIONS

The present application claims priority under 35 U.S.C §119(a) to Korean Application No. 10-2025-0063533, filed in the Korean Intellectual Property Office on May 15, 2025, the entire contents of which application is incorporated herein by reference.

### BACKGROUND

### 1. Technical Field

The present disclosure relates to internal voltage generating circuits that generate internal voltages and methods of generating internal voltages.

### 2. Related Art

Memory devices generate and use various internal voltages from externally supplied power voltages. For example, memory devices generate and use various internal voltages set to 1.2 V, 0.8 V, and 2.0 V, etc., according to operating characteristics of internal circuits, using an external voltage of 1.8 V. Memory devices use a low drop-out regulator (LDO), a charge pump, and a bandgap reference circuit to generate internal voltages.

The internal voltage generated in a memory device may vary based on changes in ambient temperature, reference voltage variation, and process changes. When the ambient temperature of a memory device varies, a threshold voltage of a transistor varies, thereby changing current characteristics of the transistor. Therefore, a voltage level of the internal voltage generated in a circuit composed of transistors varies based on the ambient temperature. In addition, the reference voltage variation may occur based on process error or temperature, and the voltage level of the internal voltage generated based on the reference voltage may also be changed due to the reference voltage variation. Furthermore, the process changes that occur based on W/L ratio, oxide thickness, and doping difference of the transistor may change resistance, capacitance, and current value in the circuit that generates the internal voltage, and thus may change the voltage level of the internal voltage.

Background technology for a driving circuit that drives an internal voltage is disclosed in Korean Patent Publication No. 10-2014-0081350.

### SUMMARY

The present disclosure describes an internal voltage generating circuit that may include a calibration voltage generating circuit configured to generate a calibration voltage, a voltage level of the calibration voltage being changed based on changes of ambient temperature, reference voltage variation, and process changes, a drive control signal generating circuit configured to drive a drive control signal based on a sense amplifier activation signal used to activate a bit line sense amplifier that senses and amplifies a bit line based on the calibration voltage, and a pull-up signal generating circuit configured to generate a plurality of pull-up signals used to drive an internal voltage based on a feedback voltage generated by voltage-dividing the internal voltage and the drive control signal.

The present disclosure describes an internal voltage generating circuit that may include a calibration voltage driving circuit configured to drive a calibration voltage based on a test reference voltage generated by adjusting a temperature reference voltage according to a calibration test mode signal set by a command and an address in an initialization operation, a drive control signal generating circuit configured to drive a drive control signal according to a sense amplifier activation signal to activate a bit line sense amplifier that senses and amplifies a bit line based on the calibration voltage, and a pull-up signal generating circuit configured to generate a plurality of pull-up signals used to drive the internal voltage based on a feedback voltage generated by voltage-dividing the internal voltage and the drive control signal.

The present disclosure describes a method of generating an internal voltage. The method may include adjusting a reference voltage according to ambient temperature corresponding to a temperature code and generating a calibration voltage based on the adjusted reference voltage, generating a drive control signal, a pulse width of the drive control signal being adjusted based on the calibration voltage, generating a first pull-up signal, a second pull-up signal, and a third pull-up signal based on the drive control signal and a feedback voltage, and driving an internal voltage based on the first pull-up signal, the second pull-up signal, and the third pull-up signal.

### BRIEF DESCRIPTION OF THE DRAWINGS

FIG. 1 illustrates an internal voltage generating circuit according to an embodiment of the present disclosure.

FIG. 2 illustrates a calibration voltage generating circuit according to an embodiment of the present disclosure.

FIG. 3 illustrates a calibration voltage driving circuit according to an embodiment of the present disclosure.

FIG. 4 illustrates a drive control signal generating circuit according to an embodiment of the present disclosure.

FIG. 5 illustrates waveforms of a drive control signal generated in a drive control signal generating circuit according to an embodiment of the present disclosure.

FIG. 6 illustrates a pull-up signal generating circuit according to an embodiment of the present disclosure.

FIG. 7 illustrates an internal voltage driving circuit according to an embodiment of the present disclosure.

FIG. 8 is a flowchart during an operation of generating an internal voltage in an internal voltage generating circuit according to an embodiment of the present disclosure.

### DETAILED DESCRIPTION

In the following description of embodiments, when a parameter is referred to as being “predetermined,” it may be intended to mean that a value of the parameter is determined in advance when the parameter is used in a process or an algorithm. The value of the parameter may be set when the process or the algorithm starts or may be set during a period in which the process or the algorithm is executed.

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

A logic “high” level and a logic “low” level may be used to describe logic levels of electric signals. A signal at a logic high level is distinguished from a signal at a logic low level. For example, when a signal at a first voltage corresponds to a signal at a logic high level, a signal at a second voltage corresponds to a signal at a logic low level. In an embodiment, the logic high level may be a voltage level that is higher than a voltage level of the logic low level. Logic levels of signals may be different or opposite according to the embodiments. For example, a signal at a logic high level in one embodiment may be at a logic low level in another embodiment, and a signal at a logic low level in one embodiment may be at a logic high level in another embodiment.

The term "binary bit set" may mean a combination of logic levels of bits included in a signal. When a logic level of each bit included in the signal is changed, the binary bit set of the signal may be set differently. For example, when a signal contains two bits and the logic level of each of the two bits contained in the signal is "logic low level, logic low level”, the binary bit set of the signal may be set to "00". In addition, when a signal contains two bits and the logic level of each of the two bits included in the signal is "logic low level, logic high level", the binary bit set of the signal may be set to "01".

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

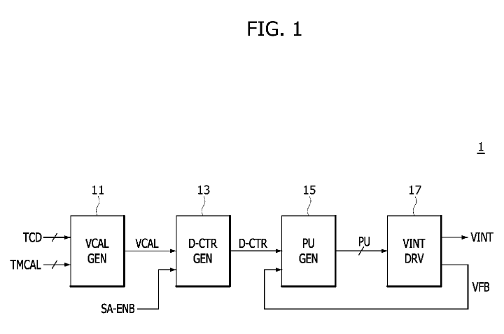

FIG. 1 illustrates an internal voltage generating circuit 1 according to an embodiment of the present disclosure.

As shown in FIG. 1, the internal voltage generating circuit 1 includes a calibration voltage generating circuit (VCAL GEN) 11, a drive control signal generating circuit (D-CTR GEN) 13, a pull up signal generating circuit (PU GEN) 15, and an internal voltage driving circuit (VINT DRV) 17.

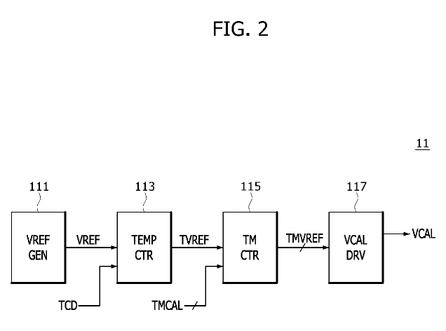

The calibration voltage generating circuit 11 generates a calibration voltage VCAL based on a temperature code TCD and a calibration test mode signal TMCAL. The calibration voltage generating circuit 11 adjusts a reference voltage, for example, a reference voltage VREF in FIG. 2, according to the ambient temperature corresponding to the temperature code TCD and drives the calibration voltage VCAL based on the adjusted reference voltage to generate the calibration voltage VCAL, the voltage level of the calibration voltage VCAL changing according to changes in the ambient temperature, reference voltage variation, and process changes. The temperature code TCD includes a plurality of bits, and each binary bit set of the bits included in the temperature code TCD corresponds to a preset ambient temperature of the internal voltage generating circuit 1.

The drive control signal generating circuit 13 is electrically connected to the calibration voltage generating circuit 11 and receives the calibration voltage VCAL from the calibration voltage generating circuit 11. The drive control signal generating circuit 13 generates a drive control signal D-CTR based on a sense amplifier activation signal SA-ENB and the calibration voltage VCAL. The sense amplifier activation signal SA-ENB is used to activate a bit line sense amplifier (not shown) that senses and amplifies a bit line containing data stored in memory cells in an active operation of a memory device (not shown). The drive control signal generating circuit 13 varies a turn-on resistance value according to the voltage level of the calibration voltage VCAL and adjusts a driving force for pull-down driving the drive control signal D-CTR by the sense amplifier activation signal SA-ENB according to the turn-on resistance value. For example, the drive control signal generating circuit 13 may decrease the turn-on resistance value as the voltage level of the calibration voltage VCAL increases to increase the driving force for pull-down driving the drive control signal D-CTR according to the sense amplifier activation signal SA-ENB, thereby reducing a pulse width of the drive control signal D-CTR. The pulse width of the drive control signal D-CTR may be set to a period in which the drive control signal D-CTR is activated.

The pull-up signal generating circuit 15 is electrically connected to the drive control signal generating circuit 13 and the internal voltage driving circuit 17, receives the drive control signal D-CTR from the drive control signal generating circuit 13, and receives a feedback voltage VFB from the internal voltage driving circuit 17. The pull-up signal generating circuit 15 generates a pull-up signal PU based on the drive control signal D-CTR and the feedback voltage VFB. The pull-up signal generating circuit 15 generates the pull-up signal PU based on whether the drive control signal D-CTR is activated and a voltage level of the feedback voltage VFB.

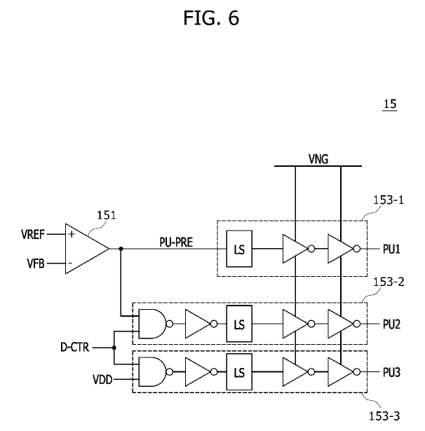

The internal voltage driving circuit 17 is electrically connected to the pull-up signal generating circuit 15 and receives the pull-up signal PU from the pull-up signal generating circuit 15. Based on the pull-up signal PU, the internal voltage driving circuit 17 generates the feedback voltage VFB and drives the internal voltage VINT. The internal voltage driving circuit 17 voltage-divides the internal voltage VINT to generate the feedback voltage VFB and drives the internal voltage VINT based on a pull-up signal PU, specifically, a first pull-up signal PU1 in FIG. 6, a second pull-up signal PU2 in FIG. 6, and a third pull-up signal PU3 in FIG. 6.

FIG. 2 illustrates a calibration voltage generating circuit 11 according to an embodiment of the present disclosure, for example, as shown in FIG. 1.

As shown in FIG. 2, the calibration voltage generating circuit 11 includes a reference voltage generating circuit (VREF GEN) 111, a temperature control circuit (TEMP CTR) 113, a test mode control circuit (TM CTR) 115, and a calibration voltage driving circuit (VCAL DRV) 117.

The reference voltage generating circuit 111 generates a reference voltage VREF that is a reference to stably generate the internal voltage VINT of FIG. 1. The reference voltage generating circuit 111 may use a bandgap reference method, a sub-bandgap reference method, or a floating-gate method. The reference voltage VREF is generated at a constant level regardless of reference voltage variation.

The temperature control circuit 113 is electrically connected to the reference voltage generating circuit 111 and receives the reference voltage VREF from the reference voltage generating circuit 111. The temperature control circuit 113 generates a temperature reference voltage TVREF based on the reference voltage VREF and a temperature code TCD. For example, when the bits included in the temperature code TCD have a first binary bit set, the temperature code TCD may correspond to a first temperature, and when the bits included in the temperature code TCD have a second binary bit set, the temperature code TCD may correspond to a second temperature. The temperature control circuit 113 generates the temperature reference voltage TVREF by adjusting the voltage level of the reference voltage VREF according to the ambient temperature corresponding to the temperature code TCD. For example, when the ambient temperature is lowered, the temperature control circuit 113 may reduce the voltage level of the reference voltage VREF according to the temperature code TCD to output the reference voltage VREF at a reduced voltage level as the temperature reference voltage TVREF; however, the present disclosure is not limited to this example. The temperature control circuit 113 generates the temperature reference voltage TVREF at the voltage level adjusted by reflecting the ambient temperature of the internal voltage generating circuit 1.

The test mode control circuit 115 is electrically connected to the temperature control circuit 113 and receives the temperature reference voltage TVREF from the temperature control circuit 113. The test mode control circuit 115 generates a test reference voltage TMVREF based on the temperature reference voltage TVREF and a calibration test mode signal TMCAL. The calibration test mode signal TMCAL includes a plurality of bits, and the binary bit set of the bits included in the calibration test mode signal TMCAL may be set by commands and addresses in an initialization operation, such as mode register set. The test mode control circuit 115 adjusts the voltage level of the temperature reference voltage TVREF according to the calibration test mode signal TMCAL to generate the test reference voltage TMVREF. The test mode control circuit 115 adjusts the voltage level of the temperature reference voltage TVREF according to the binary bit set of the calibration test mode signal TMCAL and outputs the temperature reference voltage TVREF of the adjusted voltage level as the test reference voltage TMVREF. The test mode control circuit 115 generates the test reference voltage TMVREF, the voltage level of the test reference voltage TMVREF being adjusted according to the calibration test mode signal TMCAL.

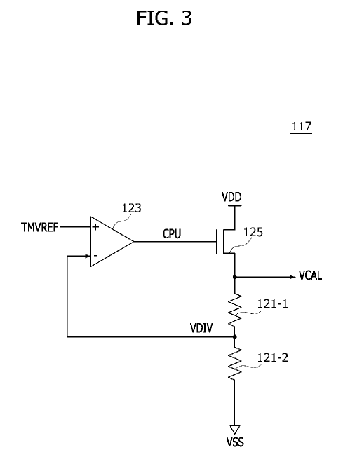

The calibration voltage driving circuit 117 is electrically connected to the test mode control circuit 115 and receives the test reference voltage TMVREF from the test mode control circuit 115. The calibration voltage driving circuit 117 drives the calibration voltage VCAL based on the test reference voltage TMVREF. The calibration voltage driving circuit 117 compares a division voltage obtained by voltage-dividing the calibration voltage VCAL, for example, a division voltage VDIV of FIG. 3, with the test reference voltage TMVREF to drive the calibration voltage VCAL. The calibration voltage driving circuit 117 may be implemented with the pull-up signal generating circuit 15 and replica circuits of the internal voltage driving circuit 17 to drive the calibration voltage VCAL by reflecting process changes occurring when driving the internal voltage VINT.

FIG. 3 illustrates a calibration voltage driving circuit 117 according to an embodiment of the present disclosure, for example, as shown in FIG. 2.

As shown in FIG. 3, the calibration voltage driving circuit 117 includes resistive elements 121-1 and 121-2, a calibration comparator 123, and a calibration driving element 125.

The resistive elements 121-1 and 121-2 voltage-divide a calibration voltage VCAL based on a ratio of resistance values of the resistive elements 121-1 and 121-2 to generate a division voltage VDIV. The resistive elements 121-1 and 121-2 are electrically connected to the calibration comparator 123 and apply the division voltage VDIV to the calibration comparator 123.

The calibration comparator 123 generates a calibration pull-up signal CPU based on the division voltage VDIV and the test reference voltage TMVREF. The calibration comparator 123 compares the division voltage VDIV with the test reference voltage TMVREF to generate the calibration pull-up signal CPU, the logic level of the calibration pull-up signal CPU being set according to a result of comparison. For example, the calibration comparator 123 may generate the calibration pull-up signal CPU that is activated at a logic high level when the division voltage VDIV is at a lower voltage level than the test reference voltage TMVREF and may generate the calibration pull-up signal CPU that is deactivated at a logic low level when the division voltage VDIV is at a higher voltage level than the test reference voltage TMVREF.

The calibration driving element 125 is electrically connected to the calibration comparator 123 and receives the calibration pull-up signal CPU from the calibration comparator 123. The calibration driving element 125 pull-up drives the calibration voltage VCAL based on the calibration pull-up signal CPU. For example, when the division voltage VDIV is at a lower voltage level than the test reference voltage TMVREF and receives the calibration pull-up signal CPU that is activated at a logic high level, the calibration driving element 125 may be turned on and may pull-up drive the calibration voltage VCAL to a power supply voltage VDD.

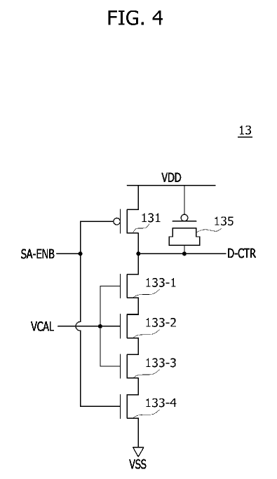

FIG. 4 illustrates a drive control signal generating circuit 13 according to an embodiment of the present disclosure, for example, as shown in FIG. 1.

As shown in FIG. 4, the drive control signal generating circuit 13 includes a PMOS transistor 131, NMOS transistors 133-1, 133-2, 133-3, and 133-4, and a capacitor 135.

The PMOS transistor 131 operates as a pull-up driving element that is turned on based on a sense amplifier activation signal SA-ENB and pull-up drives the drive control signal D-CTR. The PMOS transistor 131 is turned on when the sense amplifier activation signal SA-ENB is activated at a logic low level and pull-up drives the drive control signal D-CTR.

The NMOS transistors 133-1, 133-2, and 133-3 are turned on based on the calibration voltage VCAL and operate as resistive elements. The turn-on resistance values of the NMOS transistors 133-1, 133-2, and2. Related Art are determined according to the voltage level of the calibration voltage VCAL. As the voltage level of the calibration voltage VCAL is increased, the turn-on resistance values of the NMOS transistors 133-1, 133-2, and 133-3 are set to be smaller. As the turn-on resistance values of the NMOS transistors 133-1, 133-2, and 133-3 are decreased, a driving force to pull-down drive the drive control signal D-CTR is increased so that the time at which the drive control signal D-CTR is deactivated becomes earlier, and a pulse width of the drive control signal D-CTR may be decreased. The NMOS transistor 133-4 is turned on based on the sense amplifier activation signal SA-ENB and operates as a pull-down driving element that pull-down drives the drive control signal D-CTR. The NMOS transistor 133-4 is turned on when the sense amplifier activation signal SA-ENB is deactivated at a logic high level, and pull-down drives the drive control signal D-CTR.

The drive control signal generating circuit 13 delays the time at which the drive control signal D-CTR is pull-down driven and is deactivated according to the sense amplifier activation signal SA-ENB, delaying by an RC delay period set by the turn-on resistance values of the NMOS transistors 133-1, 133-2, and 133-3 and the capacitance of the capacitor 135. The drive control signal generating circuit 13 may reduce the driving force to pull-down drive the drive control signal D-CTR based on the NMOS transistors 133-1, 133-2, and 133-3, the turn-on resistance values of the NMOS transistors 133-1, 133-2, and 133-3 being set to be smaller as the voltage level of the calibration voltage VCAL is increased. Accordingly, the pulse width in which the drive control signal D-CTR generated in the drive control signal generating circuit 13 is activated decreases as the voltage level of the calibration voltage VCAL increases and increases as the voltage level of the calibration voltage VCAL decreases.

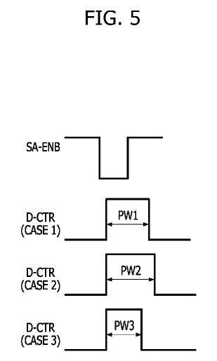

FIG. 5 illustrates waveforms of a drive control signal D-CTR generated in a drive control signal generating circuit 13 according to an embodiment of the present disclosure, for example, as shown in FIG. 4.

A first case CASE1 refers to a case in which a calibration voltage VCAL of a first voltage level is received by the drive control signal generating circuit 13. A second case CASE2 refers to a case in which the calibration voltage VCAL of a second voltage level is received by the drive control signal generating circuit 13. A third case CASE3 refers to a case in which the calibration voltage VCAL of a third voltage level is received by the drive control signal generating circuit 13. In the state in which the first case CASE1, the second case CASE2, and the third case CASE3 are set, the waveforms of the drive control signal D-CTR generated by the drive control signal generating circuit 13 are as follows. However, it is assumed that the second voltage level is set to be lower than the first voltage level, and the third voltage level is set to be higher than the first voltage level.

As shown in FIG. 5, in the first case CASE1 in which the calibration voltage VCAL of the first voltage level is received by the drive control signal generating circuit 13, the drive control signal D-CTR having a first pulse width PW1 is generated. In the second case CASE2 in which the calibration voltage VCAL of the second voltage level that is lower than the first voltage level is received by the drive control signal generating circuit 13, a turn-on resistance value of the calibration voltage VCAL becomes greater than that which is in the first case CASE1. Accordingly, in the second case CASE2, the drive control signal D-CTR having a second pulse width PW2 set to be greater than the first pulse width PW1 is generated. Meanwhile, in the third case CASE3 in which the calibration voltage VCAL of the third voltage level that is higher than the first voltage level is received by the drive control signal generating circuit 13, the turn-on resistance value of the calibration voltage VCAL becomes smaller than that which is in the first case CASE1. Accordingly, in the third case CASE3, the drive control signal D-CTR having a third pulse width PW3 set to be smaller than the first pulse width PW1 is generated.

FIG. 6 illustrates a pull-up signal generating circuit 15 according to an embodiment of the present disclosure, for example, as shown in FIG. 1.

As shown in FIG. 6, the pull-up signal generating circuit 15 includes a comparator 151, a first pull-up signal generating circuit 153-1, a second pull-up signal generating circuit 153-2, and a third pull-up signal generating circuit 153-3.

The comparator 151 generates a pre-driver pull-up signal PU-PRE based on a feedback voltage VFB and a reference voltage VREF. The comparator 151 compares the feedback voltage VFB with the reference voltage VREF and generates the pre-driver pull-up signal PU-PRE, the logic level of the pre-driver pull-up signal PU-PRE being set according to a result of comparison. For example, the comparator 151 may generate the pre-driver pull-up signal PU-PRE of a logic high level when the feedback voltage VFB is at a lower voltage level than the reference voltage VREF and may generate the pre-driver pull-up signal PU-PRE of a logic low level when the feedback voltage VFB is at a higher voltage level than the reference voltage VREF.

The first pull-up signal generating circuit 153-1 is electrically connected to the comparator 151 and receives the pre-driver pull-up signal PU-PRE from the comparator 151. The first pull-up signal generating circuit 153-1 generates a first pull-up signal PU1 based on the pre-driver pull-up signal PU-PRE. The first pull-up signal generating circuit 153-1 includes a level shifter LS and a buffer, and the first pull-up signal generating circuit 153-1 level-shifts the pre-driver pull-up signal PU-PRE through the level shifter LS and generates the first pull-up signal PU1 through the buffer that operates with an operating voltage VNG. The operating voltage VNG may be set at a lower voltage level than a power supply voltage VDD, but this is only an example and the present disclosure is not limited thereto. For example, the first pull-up signal generating circuit 153-1 may generate the first pull-up signal PU1 activated at a logic high level when the pre-driver pull-up signal PU-PRE is activated at a logic high level.

The second pull-up signal generating circuit 153-2 is electrically connected to the comparator 151 and receives the pre-driver pull-up signal PU-PRE from the comparator 151. The second pull-up signal generating circuit 153-2 generates a second pull-up signal PU2 based on the pre-driver pull-up signal PU-PRE and a drive control signal D-CTR. The second pull-up signal generating circuit 153-2 includes a level shifter LS and a buffer, and the second pull-up signal generating circuit 153-2 level-shifts a signal obtained by performing an AND operation on the pre-driver pull-up signal PU-PRE and the drive control signal D-CTR through the level shifter LS and generates the second pull-up signal PU2 through the buffer driven to the operating voltage VNG. For example, the second pull-up signal generating circuit 153-2 may generate the second pull-up signal PU2 activated at a logic high level when both the pre-driver pull-up signal PU-PRE and the drive control signal D-CTR are activated at a logic high level.

The third pull-up signal generating circuit 153-3 generates a third pull-up signal PU3 based on the drive control signal D-CTR. The third pull-up signal generating circuit 153-3 includes a level shifter LS and a buffer, and the third pull-up signal generating circuit 153-3 level-shifts a signal obtained by performing an AND operation on the drive control signal D-CTR and the power supply voltage VDD through the level shifter LS and generates the third pull-up signal PU3 through the buffer driven to the operating voltage VNG. For example, the third pull-up signal generating circuit 153-3 may generate the third pull-up signal PU3 activated at a logic high level when the drive control signal D-CTR is activated at a logic high level.

The pull-up signal generating circuit 15 generates an activated first pull-up signal PU1 according to the pre-driver pull-up signal PU-PRE that is activated when the feedback voltage VFB is at a lower voltage level than the reference voltage VREF. The pull-up signal generating circuit 15 generates an activated second pull-up signal PU2 when the pre-driver pull-up signal PU-PRE and the drive control signal D-CTR are activated. The pull-up signal generating circuit 15 generates an activated third pull-up signal PU3 when the drive control signal D-CTR is activated. The pull-up signal generating circuit 15 adjusts the periods in which each of the second pull-up signal PU2 and the third pull-up signal PU3 is activated based on the drive control signal D-CTR, the pulse width of the drive control signal D-CTR being adjusted according to changes in ambient temperature, reference voltage variation, and process changes.

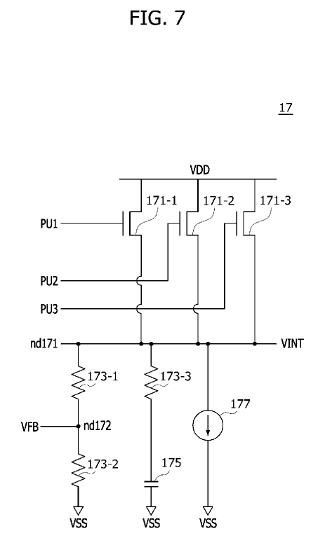

FIG. 7 illustrates an internal voltage driving circuit 17 according to an embodiment of the present disclosure, for example, as shown in FIG. 1.

As shown in FIG. 7, the internal voltage driving circuit 17 includes a first driving element 171-1, a second driving element 171-2, a third driving element 171-3, resistive elements 173-1, 173-2, and 173-3, a capacitor 175, and a current source 177.

The first driving element 171-1 is turned on based on a first pull-up signal PU1 and operates as a pull-up driving element that pull-up drives an internal voltage VINT to a power supply voltage VDD. For example, the first driving element 171-1 may be turned on when the first pull-up signal PU1 is activated and pull-up drives the internal voltage VINT to the power supply voltage VDD. The first pull-up signal PU1 is activated at a logic high level according to a pre-driver pull-up signal PU-PRE of FIG. 6 that is activated when the feedback voltage VFB is at a lower voltage level than the reference voltage VREF.

The second driving element 171-2 is turned on based on a second pull-up signal PU2 and operates as a pull-up driving element that pull-up drives the internal voltage VINT to the power supply voltage VDD. For example, the second driving element 171-2 may be turned on when the second pull-up signal PU2 is activated and pull-up drives the internal voltage VINT to the power supply voltage VDD. The second pull-up signal PU2 is activated at a logic high level when the feedback voltage VFB is at a lower voltage level than the reference voltage VREF and receives the drive control signal D-CTR that is activated by an activated sense amplifier activation signal SA-ENB. The second driving element 171-2 is set to have a driving force greater than that of the first driving element 171-1, but this is only an example and the present disclosure is not limited thereto.

The third driving element 171-3 is turned on based on a third pull-up signal PU3 and operates as a pull-up driving element that pull-up drives the internal voltage VINT to the power supply voltage VDD. For example, the third driving element 171-3 may be turned on when the third pull-up signal PU3 is activated and pull-up drives the internal voltage VINT to the power supply voltage VDD. The third pull-up signal PU3 is activated at a logic high level when the drive control signal D-CTR that is activated by the activated sense amplifier activation signal SA-ENB is received. The third driving element 171-3 is set to have a driving force greater than that of the first drive element 171-1 and smaller than that of the second drive element 171-2, but this is only an example and the present disclosure is not limited thereto.

The resistive elements 173-1 and 173-2 are connected in series between a node nd171 from which the internal voltage VINT is output and a ground voltage VSS supply terminal. The resistive elements 173-1 and 173-2 voltage-divide the internal voltage VINT according to a ratio of resistance values of the resistive elements 173-1 and 173-2 and output the feedback voltage VFB to a node nd172.

The resistive element 173-3 and the capacitor 175 are connected in series between the node nd171 from which the internal voltage VINT is output and the ground voltage VSS supply terminal. The resistive element 173-3 and the capacitor 175 maintain the voltage level of the internal voltage VINT stably.

The current source 177 is connected between the node nd171 from which the internal voltage VINT is output and the ground voltage VSS supply terminal. The current source 177 discharges a constant current to stably maintain the voltage level of the internal voltage VINT even when a load resistance of the node nd171 from which the internal voltage VINT is output is changed.

The internal voltage driving circuit 17 adjusts a period in which the internal voltage VINT is driven to the power supply voltage VDD based on the second pull-up signal PU2 and the third pull-up signal PU3, the activation periods of the second pull-up signal PU2 and the third pull-up signal PU3 being adjusted according to changes in ambient temperature, reference voltage variation, and process changes. Accordingly, the voltage level of the internal voltage VINT may be stably maintained even with the changes in ambient temperature, the reference voltage variation, and the process changes.

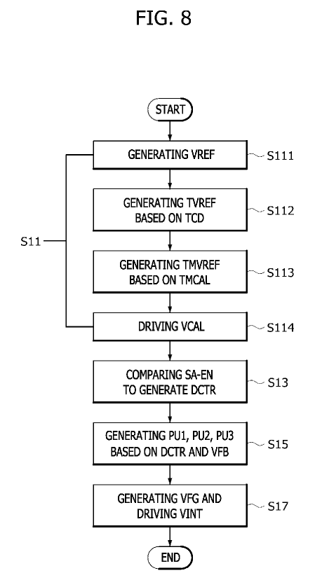

FIG. 8 is a flowchart during an operation of generating an internal voltage VINT by an internal voltage generating circuit 1 according to an embodiment of the present disclosure, for example, as shown in FIG. 1.

First, a calibration voltage generating circuit 11 adjusts a reference voltage VREF according to the ambient temperature corresponding to a temperature code TCD and drives a calibration voltage VCAL based on the adjusted reference voltage, thereby generating the calibration voltage VCAL, the voltage level of the calibration voltage VCAL changing according to changes in the ambient temperature, reference voltage variation, and process changes S11. The operation S11 of the calibration voltage generating circuit 11 generating the calibration voltage VCAL includes an operation S111 of a reference voltage generating circuit 111 generating the reference voltage VREF at a constant voltage level regardless of the reference voltage variation. In addition, the operation S11 also includes an operation S112 of the temperature control circuit 113 adjusting the voltage level of the reference voltage VREF according to the ambient temperature corresponding to the temperature code TCD and generating a temperature reference voltage TVREF based on the reference voltage VREF, the voltage level of the reference voltage VREF having been adjusted. In addition, the operation S11 also includes an operation S113 of the test mode control circuit 115 adjusting the voltage level of the temperature reference voltage TVREF according to the binary bit set of the calibration test mode signal TMCAL and generating a test reference voltage TMVREF based on the temperature reference voltage TVREF, the voltage level of the temperature reference voltage TVREF having been adjusted. In addition, the operation S11 also includes an operation S114 that drives the calibration voltage VCAL based on the test reference voltage TMVREF.

Next, a drive control signal generating circuit 13 varies the turn-on resistance value according to the voltage level of the calibration voltage VCAL and adjusts the driving force to pull-down drive the drive control signal D-CTR to the varied turn-on resistance value based on a sense amplifier activation signal SA-ENB, thereby generating the drive control signal D-CTR with a controlled pulse width S13. The pulse width in which the drive control signal D-CTR generated by the drive control signal generating circuit 13 is activated is decreased as the voltage level of the calibration voltage VCAL is increased and is increased as the voltage level of the calibration voltage VCAL is decreased.

Next, a pull-up signal generating circuit 15 generates a first pull-up signal PU1, a second pull-up signal PU2, and a third pull-up signal PU3 based on the drive control signal D-CTR and the feedback voltage VFB (S15). When the feedback voltage VFB is at a lower voltage level than the reference voltage VREF and a pre-driver pull-up signal PU-PRE is activated, the first pull-up signal PU1 is activated and generated in the pull-up signal generating circuit 15. In the pull-up signal generating circuit 15, the pre-driver pull-up signal PU-PRE is received as activated when the feedback voltage VFB is at a lower voltage level than the reference voltage VREF, and the second pull-up signal PU2 is activated and generated when the drive control signal D-CTR is received by the activated sense amplifier activation signal SA-ENB. In the pull-up signal generating circuit 15, when the drive control signal D-CTR that is activated by the activated sense amplifier activation signal SA-ENB is received, the third pull-up signal PU3 is activated and generated. In the pull-up signal generating circuit 15, the second pull-up signal PU2 and the third pull-up signal PU3, the activation periods of which are adjusted according to the pulse width of the drive control signal D-CTR, are generated. The activation periods of the second pull-up signal PU2 and the third pull-up signal PU3 are adjusted by the changes in ambient temperature, the reference voltage variation, and the process changes.

Finally, an internal voltage driving circuit 17 voltage-divides the internal voltage VINT to generate the feedback voltage VFB, and drives the internal voltage VINT based on the first pull-up signal PU1, the second pull-up signal PU2, and the third pull-up signal PU3 (S17). In the first driving element 171-1 of the internal voltage driving circuit 17, when the voltage level of the feedback voltage VFB is lower than the voltage level of the reference voltage VREF and the activated first pull-up signal PU1 is received, the internal voltage VINT is pull-up driven to the power supply voltage VDD. In the third driving element 171-3 of the internal voltage driving circuit 17, when the third pull-up signal PU3 that is activated by the drive control signal D-CTR is received, the internal voltage VINT is pull-up driven to the power supply voltage VDD. In the second driving element 171-2 of the internal voltage driving circuit 17, when the feedback voltage VFB is at a lower voltage level than the reference voltage VREF and the third pull-up signal PU3 that is activated by the drive control signal D-CTR is received, the internal voltage VINT is pull-up driven to the power supply voltage VDD.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions. All changes within the meaning and range of equivalency of the claims are included within their scope.

What is claimed is:

1. An internal voltage generating circuit comprising:
a calibration voltage generating circuit configured to generate a calibration voltage, a voltage level of the calibration voltage being changed based on changes of ambient temperature, reference voltage variation, and process changes;
a drive control signal generating circuit configured to drive a drive control signal based on a sense amplifier activation signal used to activate a bit line sense amplifier that senses and amplifies a bit line based on the calibration voltage; and
a pull-up signal generating circuit configured to generate a plurality of pull-up signals used to drive an internal voltage based on a feedback voltage generated by voltage-dividing the internal voltage and the drive control signal.

2. The internal voltage generating circuit of claim 1, wherein the calibration voltage generating circuit is configured to:
adjust the voltage level of the calibration voltage based on a temperature code; and
adjust the voltage level of the calibration voltage based on a calibration test mode signal.

3. The internal voltage generating circuit of claim 1, wherein the calibration voltage generating circuit receives a temperature code including bits having a binary bit set corresponding to ambient temperature of the internal voltage generating circuit.

4. The internal voltage generating circuit of claim 1, wherein the calibration voltage generating circuit comprises:
a temperature control circuit configured to adjust a reference voltage based on a temperature code corresponding to ambient temperature to generate a temperature reference voltage;
a test mode control circuit configured to adjust the temperature reference voltage based on the calibration test mode signal to generate a test reference voltage; and
a calibration voltage driving circuit configured to drive the calibration voltage based on the test reference voltage.

5. The internal voltage generating circuit of claim 4, wherein the calibration voltage driving circuit is implemented with the pull-up signal generating circuit and replica circuits of an internal voltage driving circuit configured to drive the internal voltage.

6. The internal voltage generating circuit of claim 4, wherein the calibration voltage driving circuit comprises:
resistive elements configured to voltage-divide the calibration voltage to generate a division voltage;
a calibration comparator configured to compare the division voltage with the test reference voltage to generate a calibration pull-up signal; and
a calibration driving element configured to drive the calibration voltage based on the calibration pull-up signal.

7. The internal voltage generating circuit of claim 1, wherein the drive control signal generating circuit is configured to:
adjust a turn-on resistance value based on the voltage level of the calibration voltage; and
adjust a driving force to pull-down drive the drive control signal based on the sense amplifier activation signal according to the adjusted turn-on resistance value.

8. The internal voltage generating circuit of claim 7, wherein the drive control signal generating circuit is configured to:
decrease the turn-on resistance value as the voltage level of the calibration voltage is increased, and
increase the driving force to pull-down drive the drive control signal according to the sense amplifier activation signal to generate the drive control signal with a reduced pulse width.

9. The internal voltage generating circuit of claim 7, wherein the drive control signal generating circuit is configured to:
increase the turn-on resistance value as the voltage level of the calibration voltage is decreased, and
decrease the driving force to pull-down drive the drive control signal according to the sense amplifier activation signal to generate the drive control signal with an increased pulse width.

10. The internal voltage generating circuit of claim 1, wherein the drive control signal generating circuit comprises:
a pull-up driving element configured to pull-up drive the calibration voltage based on the sense amplifier activation signal;
a resistive element, a turn-on resistance value of the resistive element being adjusted based on the calibration voltage; and
a pull-down driving element configured to pull-down drive the calibration voltage based on the sense amplifier activation signal.

11. The internal voltage generating circuit of claim 1,
wherein the plurality of pull-up signals comprise a first pull-up signal, a second pull-up signal, and a third pull-up signal,
wherein the pull-up signal generating circuit is configured to:
generate the first pull-up signal that is activated according to a pre-driver pull-up signal,
generate the second pull-up signal based on the pre-driver pull-up signal and the drive control signal, and
generate the third pull-up signal based on the drive control signal,
wherein the pre-driver pull-up signal is activated when the feedback voltage is at a lower voltage level than a reference voltage, and
wherein the drive control signal is activated based on the sense amplifier activation signal and a pulse width in which the drive control signal is activated is adjusted based on the voltage level of the calibration voltage.

12. The internal voltage generating circuit of claim 11, wherein the pull-up signal generating circuit comprises:
a comparator configured to compare the feedback voltage with the reference voltage to generate the pre-driver pull-up signal;
a first pull-up signal generating circuit configured to generate the first pull-up signal based on the pre-driver pull-up signal;
a second pull-up signal generating circuit configured to generate the second pull-up signal based on the pre-driver pull-up signal and the drive control signal; and
a third pull-up signal generating circuit configured to generate the third pull-up signal based on the drive control signal.

13. The internal voltage generating circuit of claim 11, further comprising an internal voltage driving circuit configured to drive the internal voltage based on the first pull-up signal, the second pull-up signal, and the third pull-up signal.

14. An internal voltage generating circuit comprising:
a calibration voltage driving circuit configured to drive a calibration voltage based on a test reference voltage generated by adjusting a temperature reference voltage according to a calibration test mode signal set by a command and an address in an initialization operation;
a drive control signal generating circuit configured to drive a drive control signal according to a sense amplifier activation signal to activate a bit line sense amplifier that senses and amplifies a bit line based on the calibration voltage; and
a pull-up signal generating circuit configured to generate a plurality of pull-up signals used to drive the internal voltage based on a feedback voltage generated by voltage-dividing the internal voltage and the drive control signal.

15. The internal voltage generating circuit of claim 14, wherein the calibration voltage driving circuit comprises:
resistive elements configured to voltage-divide the calibration voltage to generate a division voltage;
a calibration comparator configured to compare the division voltage with the test reference voltage to generate a calibration pull-up signal; and
a calibration driving element configured to drive the calibration voltage based on the calibration pull-up signal.

16. The internal voltage generating circuit of claim 14, wherein the drive control signal generating circuit is configured to:
adjust a turn-on resistance value based to the voltage level of the calibration voltage; and
adjust a driving force to pull-down drive the drive control signal based on the sense amplifier activation signal according to the adjusted turn-on resistance value.

17. The internal voltage generating circuit of claim 16, wherein the drive control signal generating circuit is configured to:
decrease the turn-on resistance value as the voltage level of the calibration voltage is increased, and
increase the driving force to pull-down drive the drive control signal according to the sense amplifier activation signal to generate the drive control signal with a reduced pulse width.

18. The internal voltage generating circuit of claim 16, wherein the drive control signal generating circuit is configured to:
increase the turn-on resistance value as the voltage level of the calibration voltage is decreased, and
decrease the driving force to pull-down drive the drive control signal according to the sense amplifier activation signal to generate the drive control signal with an increased pulse width.

19. The internal voltage generating circuit of claim 16, wherein the drive control signal generating circuit comprises:
a pull-up driving element configured to pull-up drive the calibration voltage based on the sense amplifier activation signal;
a resistive element, a turn-on resistance value of the resistive element being adjusted based on the calibration voltage; and
a pull-down driving element configured to pull-down drive the calibration voltage based on the sense amplifier activation signal.

20. The internal voltage generating circuit of claim 14,
wherein the plurality of pull-up signals comprises a first pull-up signal, a second pull-up signal, and a third pull-up signal,
wherein the pull-up signal generating circuit is configured to:
generate the first pull-up signal that is activated according to a pre-driver pull-up signal,
generate the second pull-up signal based on the pre-driver pull-up signal and the drive control signal, and
generate the third pull-up signal based on the drive control signal,
wherein the pre-driver pull-up signal is activated when the feedback voltage is at a lower voltage level than a reference voltage, and
wherein the drive control signal is activated based on the sense amplifier activation signal and a pulse width in which the drive control signal is activated is adjusted based on the voltage level of the calibration voltage.

21. The internal voltage generating circuit of claim 20, further comprising an internal voltage driving circuit configured to drive the internal voltage based on the first pull-up signal, the second pull-up signal, and the third pull-up signal.

22. A method of generating an internal voltage, the method comprising:
adjusting a reference voltage according to ambient temperature corresponding to a temperature code and generating a calibration voltage based on the adjusted reference voltage;
generating a drive control signal, a pulse width of the drive control signal being adjusted based on the calibration voltage;
generating a first pull-up signal, a second pull-up signal, and a third pull-up signal based on the drive control signal and a feedback voltage; and
driving an internal voltage based on the first pull-up signal, the second pull-up signal, and the third pull-up signal.

23. The method of claim 22, wherein generating the calibration voltage comprises:
adjusting a temperature reference voltage according to a calibration test mode signal and generating a test reference voltage based on the adjusted temperature reference voltage; and
driving the calibration voltage based on the test reference voltage.

24. The method of claim 22, wherein, in generating the drive control signal,
a turn-on resistance value varies according to the voltage level of the calibration voltage, and
a driving force to pull-down drive the drive control signal is adjusted according to the varied turn-on resistance value based on the sense amplifier activation signal to activate a bit line sense amplifier that senses and amplifies a bit line.

25. The method of claim 22, wherein in generating the drive control signal,
the turn-on resistance value is decreased as the voltage level of the calibration voltage is increased, and
the driving force to pull-down drive the drive control signal is increased according to the sense amplifier activation signal to generate the drive control signal with a reduced pulse width.

26. The method of claim 22, wherein generating the first pull-up signal, the second pull-up signal, and the third pull-up signal comprises:
comparing the feedback voltage with the reference voltage to generate a pre-driver pull-up signal;
generating the first pull-up signal based on the pre-driver pull-up signal;
generating the second pull-up signal based on the pre-driver pull-up signal and the drive control signal; and
generating the third pull-up signal based on the drive control signal.
